(19) United States
(12) Patent Application Publication
(10) Pub. No.: US 2008/0241355 A1
(43) Pub. Date: Oct. 2, 2008

(54) THIN FILM TRANSISTOR DEVICES HAVING HIGH ELECTRON MOBILITY AND STABILITY

(75) Inventors: Tae Kyung Won, San Jose, CA (US); John M. White, Hayward, CA (US); Ya-Tang Yang, Santa Clara, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 11/694,353

(22) Filed: Mar. 30, 2007

(51) Int. Cl. B05D 5/12

(52) U.S. Cl. 427/58

(57) ABSTRACT

Methods for depositing a gate insulator layer and a semiconductor layer onto a large area substrate with improved film uniformity, device mobility and stability are provided. The film properties of the gate insulator layer and the semiconductor layer are selected so that higher electron mobility (greater than 0.7 centimeters squared per voltage per second) is obtained, thereby efficiently enhancing the performance and stability of TFT devices. Improvements in film uniformity may also be realized.

### BACKGROUND OF THE INVENTION

1. Field of the Invention

Embodiments of the present invention generally relate to methods to improve mobility of thin film transistors devices. More particularly, this invention relates to methods to improve mobility of thin film transistors devices by depositing thin films with engineered film properties on large area substrates.

2. Description of the Related Art

Plasma display panels and liquid crystal displays are frequently used for flat panel displays. Liquid crystal displays (LCD) generally contain two glass substrates joined together with a layer of a liquid crystal material sandwiched therebetween. The glass substrate may be a semiconductor substrate, or may be a transparent substrate such as a glass, quartz, sapphire, or a clear plastic film. The LCD may also contain light emitting diodes for back lighting. Furthermore, organic light emitting diodes (OLEDs) having been used for liquid crystal displays, and these organic light emitting diodes require TFTs for addressing the activity of the displays.

As the resolution requirements for liquid crystal displays increase, it has become desirable to control a large number of separate areas of the liquid crystal cell, called pixels. In a modern display panel, more than 1,000,000 pixels may be present. At least the same number of transistors is formed on the glass substrate so that each pixel can be switched between an energized and de-energized state relative to the other pixels disposed on the substrate. Commonly, there are three transistors per pixel.

One type of thin film transistor device used is a back channel etched thin film transistor (BCE TFT). A major CVD process step in conventional BCE TFT processing is the sequential deposition of three layers; a gate insulator layer of typically a gate silicon nitride (SiNₓ), gate silicon oxide, or both, followed by an semiconductor layer of amorphous silicon (a-Si), and then a thin doped semiconductor layer of n-type or p-type amorphous silicon (N⁺/P⁺-a-Si).

Several publications address different drawbacks and disadvantages of conventionally deposited gate silicon nitride film (SiNₓ) and semiconductor layer of amorphous silicon film (a-Si). Young-Bae Park et al., in an article entitled: “Bulk and Interface Properties of Low-temperature Silicon Nitride Films Deposited by Remote Plasma Enhanced Chemical Vapor Deposition”, Journal of Materials Science: Materials in Electronics Volume 23 (2001) Page 515-522, describe problems which occur when a gate dielectric, rather than being SiNₓ, is a hydrogenated silicon nitride film (a-SiNₓ:H). PECVD a-SiNₓ:H thin films are said to be widely used as a gate dielectric for a-Si:H TFT applications, due to good interfacial properties between an a-Si:H layer and an a-Si:Nₓ:H layer. However, the a-Si:H TFTs having a SiNₓ:H gate dielectric is reported to have instability problems, such as threshold voltage shift and inverse subthreshold slope under a D.C. gate voltage bias. Instability problems are reported as being caused by high trap density in the SiNₓ:H film and defects created at the a-Si:H/SiNₓ:H interface. Charge trapping in SiNₓ:H is from electron injection under an applied field and due to localized states of the Si dangling bonds, Si—H and N—H bonds in the forbidden gap. The authors claim that PECVD SiNₓ:H dielectric films are not useful as a gate insulator because they contain large amounts of bonded hydrogen (20 percent-40 percent) in the form of N—H and Si—H bonds. Moreover, the SiNₓ:H electrical insulator having a reduction in the amounts of bonded hydrogen in the form of Si—H bonds are reported to easily lose hydrogen to form a dangling bond of the kind known to reduce performance of the TFT device over time.

A presentation entitled: “Low Temperature a-Si:H TFT on Plastic Films: Materials and Fabrication Aspects”, by Andrei Sazonov et al., Proc. 23rd International Conference on Microelectronics (MIEL 2002), Vol. 2, NIS, Yugoslavia, 12-15 May 2002, related to fabrication technology for a-Si:H thin film transistors at 120 degrees Celsius for active matrix OLED displays on flexible plastic substrates. The TFTs produced were reported as demonstrating performance very close to those fabricated at 260 degrees Celsius. The authors claim that with the proper pixel integration, amorphous hydrogenated silicon (a-Si:H) TFTs are capable of supplying current sufficiently high enough to achieve required display brightness and, thus, can be a cost-effective solution for active matrix OLED displays.

The silicon nitride films used to produce the fabricated TFT samples were amorphous silicon nitride deposited at 120 degrees Celsius by PECVD from SiH₄ and NH₃ gaseous precursors. The film is reported to have a lower mass density and higher hydrogen concentration in comparison with films fabricated at 260 degrees Celsius to 320 degrees Celsius. In the study, a series of a-SiNₓ:H films with a [N]:[Si] ratio ranging from 1.4 to 1.7 were deposited (at the 120 degrees Celsius). The hydrogen content in the films was in the range of 25 to 40 atomic percent. Generally, the films with a higher [N]:[Si] ratio are reported to have a higher mass density and a higher compressive stress. The resistivity of a-SiNₓ:H films estimated at the field of 1 MV/cm was reported to be in the range of 10¹⁴-10¹⁶ Ohm cm, and the films with a higher [N]:[Si] ratio were reported to have a higher breakdown field and dielectric constant than their lower N-content counterparts.

Compared to higher temperature counterparts, the lower temperature a-SiNₓ films are characterized by higher hydrogen content. The N-rich films with a hydrogen concentration of about 40 percent or more exhibit hydrogen bonded predominantly to nitrogen atoms, with a high [N]:[Si] ratio achieved solely due to the high concentration of N—H bonds. The TFT produced a plastic film substrate at lower temperatures require a higher threshold voltage (4-5V) than the TFTs produced on glass at the higher temperatures. As a result, the ON current observed for TFTs produced at the lower temperatures is lower. Although the performance properties of these TFTs comply with the requirements for OLED applications, it is apparent that it would be beneficial to lower the threshold voltage of the TFTs produced at the 120 degrees Celsius temperature.

Thus, we have realized that the performance capabilities of the TFT are a direct result of properties of the films formed during fabrication of the TFTs. Different properties of the films are originated from different chemical structural characteristics of the films. The structural characteristic of the films depend directly upon the process conditions and relative amounts of precursors which are used during formation of the films which make up the TFTs. Therefore, film properties of a-SiNₓ:H film or a-Si:H film produced by conventional plasma enhanced chemical vapor deposition (PECVD) processes may vary significantly, thereby resulting in various device performance in TFT devices.

As the size of the flat panel displays increase, the uniformity of the individual films produced across the increased surface area has become increasingly difficult to control. Since electron mobility in TFTs dominates device performance, a greater mobility of electrons in amorphous silicon TFTs is desired. An amorphous silicon TFT with high electron mobility would allow more pixel area for light transmission and integration of circuitry, thereby allowing brighter LCD, higher overall electrical efficiency, faster response time and higher resolution displays. The limited electron mobility inherent to conventionally processed amorphous silicon TFTs results in limited frame refresh rates and pixel densities. Moreover, a stable and reliable operation of LCD with lower threshold voltage shift also prevails the overall performance of the TFT devices.

Therefore, there is a need for TFT devices having improved electron mobility and stability and a method for manufacturing the same.

### SUMMARY OF THE INVENTION

Embodiments of the invention generally provide nitrogen containing film and/or a stack of films including a nitrogen containing film and a silicon containing film, engineered to provide high electron mobility and stable device performance. Other embodiments include a TFT device with improved electron mobility and stability and a method of manufacturing the same. The TFT device is made by controlling film properties of a gate insulator layer and a semiconductor layer deposited in the device. By depositing the gate insulator layer and the semiconductor layer with selected film properties, higher electron mobility (greater than 0.7 centimeters squared per voltage per second) is obtained, thereby efficiently enhancing the performance of TFT devices. Improvements in film uniformity may also be realized.

In one embodiment, a method for fabricating a TFT device includes providing a substrate into a first processing chamber, supplying a first gas mixture into the processing chamber, and depositing a nitrogen containing layer on the substrate in the first chamber, wherein the nitrogen containing layer film has film properties including a N:Si stiochiometry ratio greater than about 1.5, a hydrogen content in the silicon bonding less than about 4.0 atomic weight percent, a wet etching rate at Buffer Oxide Etchant 6:1 solution less than about 400 Å per minute, an optical energy gap (E₀₄) greater than about 5.4 electron Voltage, and a dielectric constant greater than about 6.85.

In another embodiment, the method includes providing a substrate into a first processing chamber, supplying a first gas mixture into the processing chamber, depositing a nitrogen containing layer on the substrate in the first chamber, wherein the nitrogen containing layer film has film properties including a N:Si stiochiometry ratio greater than about 1.5, a hydrogen content in the silicon bonding less than about 4.0 atomic weight percent, a wet etching rate at Buffer Oxide Etchant 6:1 solution less than about 400 Å per minute, an optical optical energy gap (E₀₄) greater than about 5.4 electron Voltage, and a dielectric constant greater than about 6.85, transferring the substrate into a second process chamber, supplying a second gas mixture into the second process chamber, and depositing a silicon containing layer over the nitrogen containing layer on the substrate in the second chamber, wherein the silicon containing layer film has film properties including an optical energy gap (E₀₄) less than about 1.84 electron Voltage, a hydrogen content in the silicon bonding less than about 7.0 atomic weight percent, and a Si—H peak area/unit thickness less than about 0.4.

In yet another embodiment, the method includes providing a substrate into a first processing chamber, supplying a first gas mixture into the processing chamber, wherein the first mixture including N₂, NH₃, and SiH₄, wherein the gas flow ratio of NH₃:SiH₄ is about 8:1 to about 4:1, the gas flow ratio of N₂:SiH₄ is about 60:1 to about 20:1, and the gas flow ratio of N₂:NH₃ is about 8.5:1 to about 4.5:1, maintaining substrate temperature between about 300 to about 360 degrees Celsius, controlling process pressure between about less than about 2 Torr, providing RF power between about 1800 Watts to about 2400 Watts, depositing a nitrogen containing layer on the substrate in the first chamber, transferring the substrate into a second process chamber, providing a second gas mixture into the second process chamber, wherein the second mixture including SiH₄ and H₂, wherein the gas flow ratio of SiH₄:H₂ is about 6:1 to about 1:1, maintaining substrate temperature between about 300 to about 360 degrees Celsius, controlling process pressure between about less than about 4 Torr, providing RF power between about less than about 400 Watts, and depositing a silicon containing layer over the nitrogen containing layer on the substrate in the second chamber.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 is a sectional view of an exemplary large area substrate processing system in which a TFT structure according to the present invention may be formed;

FIG. 2 depicts a sectional view of the processing chamber of FIG. 1 in which a TFT structure according to the present invention may be formed;

FIG. 3 depicts one embodiment of a TFT structure according to the present invention;

FIG. 4 depicts a process flow diagram of one embodiment of a method of forming a TFT structure according to the present invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the invention generally provide a nitrogen containing film and/or a stack of films including a nitrogen containing film and a silicon containing film, engineered to provide high electron mobility and stable device performance. Other embodiments of the invention generally provide a TFT device and method for forming the same. The methods described herein advantageously facilitate electron mobility and stability in the deposited films. These films are particularly useful in forming a TFT. The high electron mobility (as compared to electron mobility in similar films deposited using conventional techniques) is enabled by a process having a synergistic regulation of parameters during formation of the films. In one embodiment, improved electron mobility and stability is achieved by depositing a silicon containing film, such as an a-Si:H film, over the a nitrogen containing film, such as a a-SiNₓ:H film, with selected film properties. The deposition process may be performed in a plasma enhanced chemical vapor deposition (PECVD) chamber, for example, AKT-1600 PECVD system, AKT-3500 PECVD system, AKT-4300 PECVD system, AKT-5500 PECVD system, AKT-10K PECVD system, AKT-15K PECVD system, AKT-25K PECVD system, AKT-40K PECVD system, AKT-50K PECVD system, all of which are all available from AKT, a division of Applied Materials, Inc., located in Santa Clara, Calif. It is also contemplated that deposition process may be performed in other suitable PECVD systems.

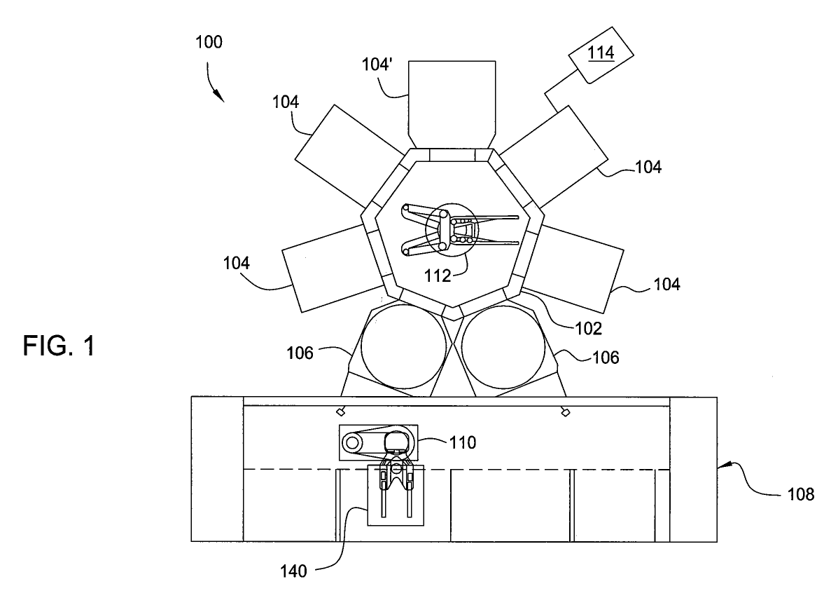

FIG. 1 is a top sectional view of one embodiment of a plasma enhanced chemical vapor deposition system 100 adapted to deposit dielectric material on large area substrates. Typically, large area substrates have a surface area (on one side) greater than or equal to about 0.35 square meters. The system 100 generally includes a central transfer chamber 120 having a plurality of processing chambers 104 coupled thereto. At least one load lock chamber 160 is coupled between the transfer chamber 120 and a factory interface 110 to facilitate transfer of substrates 140 between the factory interface 110 and the processing chambers 104. The system 100 also includes an interface robot 116 disposed in the factory interface 110 and a transfer robot 130 disposed in the transfer chamber 120 to enable substrate movement through the load lock chambers 160 and around the system 100.

Each processing chamber 104 is adapted for processing a large area substrate and typically has a volume of at least about 360 liters. Each processing chamber 104 is typically coupled to a respective gas delivery system (One gas deliver system 114 is shown for clarity in FIG. 1). The gas delivery system 114 generally provides process gas to the processing chamber 104.

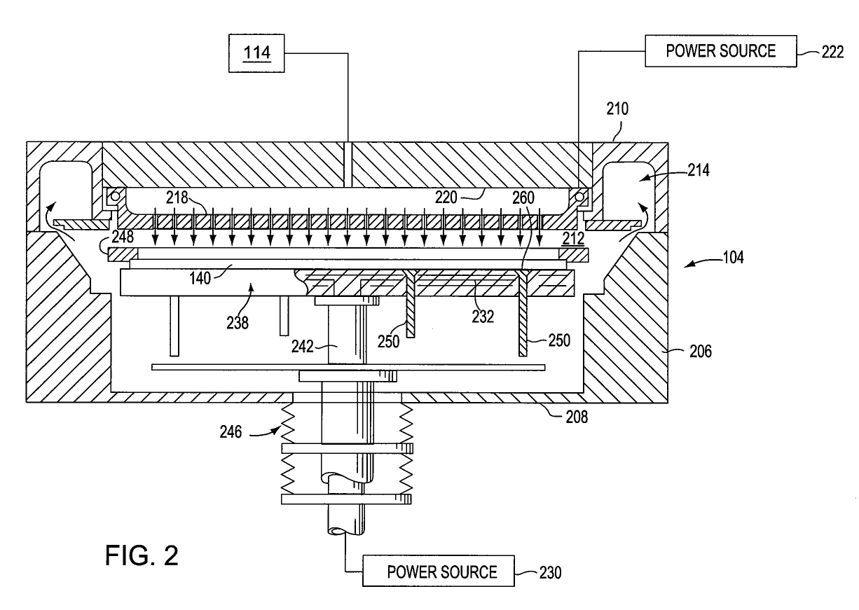

FIG. 2 depicts a sectional view of the processing chamber 104 of FIG. 1 having one embodiment of the gas delivery system 114 coupled thereto. The processing chamber 104 has walls 206, a bottom 208, and a lid assembly 210 that define a process volume 212. The process volume 212 is typically accessed through a port (not shown) in the walls 206 that facilitate movement of a substrate 140 into and out of the processing chamber 104. The walls 206 and bottom 208 are typically fabricated from an aluminum or other material compatible with processing chemistries. The lid assembly 210 contains a pumping plenum 214 that couples the process volume 212 to an exhaust port (that includes various pumping components, not shown).

The lid assembly 210 is supported by the walls 206 and can be removed to service the processing chamber 104. The lid assembly 210 is generally comprised of aluminum and may additionally contain heat transfer fluid channels for regulating the temperature of the lid assembly 210 by flowing heat transfer fluid therethrough.

A distribution plate 218 is coupled to an interior side 220 of the lid assembly 210. The distribution plate 218 is typically fabricated from aluminum and includes a perforated area through which process and other gases supplied from the gas delivery system 114 are delivered to the substrate 140 seated on the substrate support 238. The perforated area of the distribution plate 218 is configured to distribute process gas in a manner that promotes uniform deposition of material on the substrate 140.

A heated substrate support assembly 238 is centrally disposed within the processing chamber 104. The support assembly 238 supports the substrate 140 during processing. The support assembly 238 has a plurality of lift pins 250 movably disposed therethrough. The lift pins 250 may be actuated to project from the support surface 260, thereby placing the substrate in a spaced-apart relation to the support assembly 238 to facilitate substrate transfer with the transfer robot 130.

A vacuum port (not shown) is disposed through the support assembly 238 and is used to apply a vacuum between the substrate 140 and the support assembly 238, securing the substrate 140 to the support assembly 238 during processing. The heating element 232, such as an electrode disposed in the support assembly 238, is coupled to a power source 230, heating the support assembly 238 and the substrate 140 positioned thereon to a predetermined temperature. Typically, the heating element 232 maintains the substrate 140 at a uniform temperature of about 150 to at least about 460 degrees Celsius.

The support assembly 238 additionally supports a circumscribing shadow frame 248. The shadow frame 248 is configured to cover the edge of the substrate 140 and is typically comprised of ceramic. Generally, the shadow frame 248 prevents deposition at the edge of the substrate 140 and support assembly 238 so that the substrate does not stick to the support assembly 238. Optionally, a purge gas is supplied between the shadow frame 248 and the support assembly 238 to assist in preventing deposition at the substrate's edge.

The support assembly 238 is coupled by a stem 242 to a lift system (not shown) that moves the support assembly 238 between an elevated position (as shown) and a lowered position. A bellows 246 provides a vacuum seal between the chamber volume 212 and the atmosphere outside the processing chamber 104 while facilitating the movement of the support assembly 238. The stem 242 additionally provides a conduit for electrical leads, vacuum and gas supply lines between the support assembly 238 and other components of the system 100.

The support assembly 238 generally is grounded such that RF power supplied by a power source 222 to the distribution plate 218 (or other electrode positioned within or near the lid assembly of the chamber) may excite the gases disposed in the process volume 212 between the support assembly 238 and the distribution plate 218. The RF power, generally having a frequency of between a few Hz to 13 MHz or higher is provided in a wattage suitable for the substrate surface area. In one embodiment, the power source 222 comprises a dual frequency source that provides a low frequency power at less than about 2 MHz (preferably about 200 to 500 kHz) and a high frequency power at greater than 13 MHz, for example, about 13.56 MHz. The frequencies may be fixed or variable. Illustratively, for a 550 mm×650 mm substrate, the low frequency power is about 0.3 to about 2 kW while the high frequency power is about 1 to about 5 kW. Generally, the power requirements decrease or increase with a corresponding decrease or increase in substrate size.

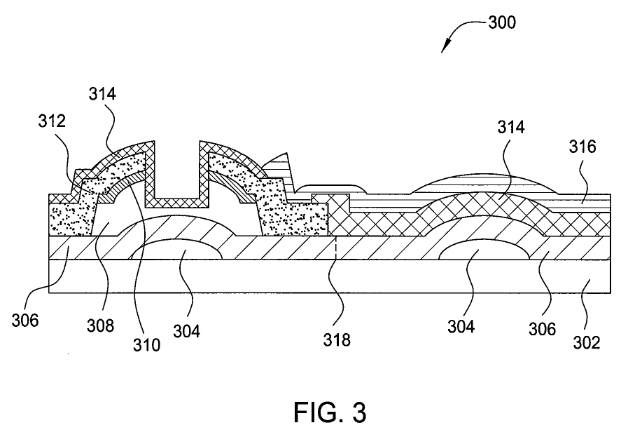

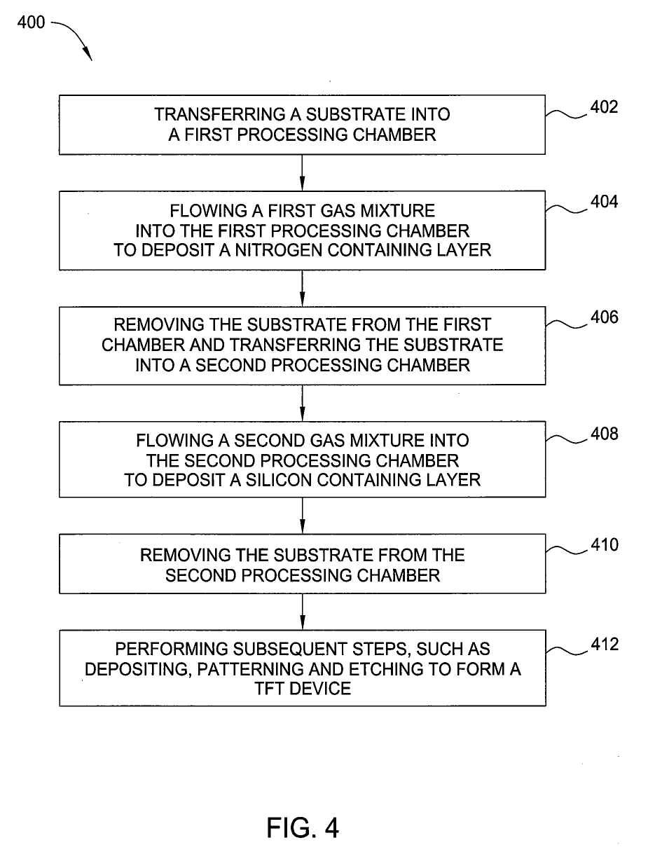

FIG. 4 illustrates a flow diagram of one embodiment of a deposition process 400 utilized to deposit thin films according to one embodiment of the invention. The process 400 in utilized to fabricate a TFT structure, one embodiment of which is shown in a schematic cross-sectional view of FIG. 3.

In a preliminary step prior to the process 400, a conductive layer is sputter deposited over a substrate 302 using techniques known in the art. In one embodiment, the substrate 302 is a glass substrate having a thickness of 0.7 mm, as shown in FIG. 3. In another embodiment, the substrate 302 may be any other suitable materials, such as semiconductor, quartz, sapphire, a plastic film, or the like. The conductive layer 304 may be a bilayer, where the bottom portion of the layer is a chrome layer, with an overlying layer of an aluminum neodymium alloy. Subsequently, the conductive layer is pattern etched using a wet etch process known in the art to provide conductive electrodes 304.

The process 400 begins at step 402 where a substrate 302 having the electrodes 304 formed thereon is transferred into a first processing chamber, such as the processing chamber 104 described in FIGS. 1-2.

At step 404, a first gas mixture is supplied into the processing chamber 104 to deposit a nitrogen containing layer 306 over the conductive electrodes 304. The nitrogen containing layer 306 serves as a gate insulator layer. The nitrogen-containing layer 306 may be an amorphous silicon nitrogen material, a nitrogen-doped silicon material, a hydrogenated silicon nitride film (SiNₓ:H) and among others. In the embodiment depicted in FIG. 3, the nitrogen-containing layer is a hydrogenated silicon nitride film (SiNₓ:H).

Several process parameters and composition of first gas mixture are regulated to control the process conditions in the process chamber, and ultimately the properties of the deposited film. In one embodiment, as listed in Table 1, the first gas mixture may include at least a silicon containing gas, such as SiH₄, supplied with at least a nitrogen containing gas. The nitrogen containing gas may include, but not limited to, nitrogen gas (N₂), ammonia gas (NH₃), a mixture of nitrogen gas and ammonia gas, among others. In another embodiment, the first gas mixture may include at least a silicon containing gas, such as SiH₄, a nitrogen containing gas and a hydrogen containing gas into the processing chamber. The hydrogen containing gas may include, but not limited to, ammonia gas (NH₃) or hydrogen gas (H₂), among others.

In an exemplary embodiment, the first gas mixture includes SiH₄, NH₃ and N₂ having a total gas flow of the first gas mixture between about 8,000 sccm to about 20,000 sccm, for example between about 10,000 sccm to about 18,000 sccm. The gas flow of SiH₄ gas is between about 100 to about 500 sccm, for example, between about 150 to about 400 sccm. The gas flow of NH₃ gas is between about 800 to about 3,000 sccm, for example, between about 1,500 to about 2,500 sccm. The gas flow of N₂ gas is between about 8,000 to about 30,000 sccm, for example, between about 10,000 to about 25,000 sccm.

Furthermore, the gas flow ratio between NH₃ and SiH₄ (NH₃:SiH₄) is about 4:1 to about 8:1, for example, about 5:1 to about 7:1. The gas flow ratio between N₂ and SiH₄ (N₂:SiH₄) is about 20:1 to about 60:1, for example, about 35:1 to about 55:1. The gas flow ratio between N₂ and NH₃ (N₂:NH₃) is about 4.5:1 to about 8.5:1, for example, about 5.5:1 to about 7.5:1.

Additionally, the substrate temperature during film deposition is maintained between about 300 degrees Celsius and about 360 degrees Celsius. The process pressure is maintained at less than about 2 Torr. The RF plasma power is regulated between about 1,800 Watts to about 2,400 Watts.

TABLE 1
Process Parameters regulated in supplying the first gas mixture.

| Process Parameters | Max. | Min. |
|---|---|---|
| SiH₄ (sccm) | 500 | 100 |
| NH₃ (sccm) | 3000 | 800 |
| N₂ (sccm) | 30000 | 8000 |
| NH₃:SiH₄ gas ratio | 8 | 4 |
| N₂:SiH₄ gas ratio | 60 | 20 |
| N₂:NH₃ gas ratio | 8.5 | 4.5 |
| Temperature (degrees Celsius) | 360 | 300 |
| Pressure (mTorr) | 2 | 0 |
| RF power at 13.56 MHz (W) | 2400 | 1800 |

The film properties of the deposited nitrogen containing gate insulator layer 306 is selected so that a desired performance requirement of a TFT device is obtained. The film properties of the deposited nitrogen containing film 306 include having electron mobility higher than 0.7 centimeters squared per voltage per second (cm²/Vs), a uniformity of film thickness below 15 percent and uniformity of film properties, such as chemical composition and structural characteristics. In one embodiment, the desired film properties are achieved by controlling the silicon-hydrogen (Si—H) bonded content of the SiNₓ:H film, measured by fourier transform infrared spectra (FTIR), to less than about 4.0 atomic percent, the stoichiometry of nitrogen to silicon (N:Si) greater than about 1.5:1, the wet etching rate in HF solution (Buffer Oxide Etchant 6:1) of less than about 400 Å per minute, optical energy gap (E₀₄) greater than about 5 electron voltage (eV), and the dielectric constant (k) greater than about 6.85, as listed in Table 2.

TABLE 2
Film properties of the nitrogen containing gate insulator layer.

| | SiNₓ:H film |
|---|---|
| Si—H bonding content | <4 percent |
| N:Si Stoichiometry | >1.5 |
| Wet Etch Rate at BOE | <400 Å/min |
| solution | |
| Optical Energy Gap (E₀₄) | >5 eV |
| Dielectric Constant (k) | >6.85 |

With the improved electron mobility of the nitrogen containing film, a lower threshold voltage shift of the device performance is also achieved. The lower threshold voltage shift enables the TFT devices to operate in a stable and reliable manner, thereby resulting in the improvement of the stability and performance of the device. In one embodiment, an improved threshold voltage shift of greater than 10% is achieved by the selected film properties of the nitrogen containing film.

At step 406, the substrate is removed from the first processing chamber and transferred into a second process chamber to perform process step 408. Alternatively, process step 408 may be the first process chamber, thereby retaining the substrate at the same chamber in which the nitrogen containing layer was deposited.

At step 408, a second gas mixture is flowed into the second process chamber to deposit a silicon containing film 308 over the nitrogen containing gate insulator layer 306 to serve as a semiconductor layer in TFT devices. The second process chamber may be a PECVD chamber, such as chambers 104 described in FIG. 1-2. The silicon containing film 308 may include, but not limited to, an amorphous (a-Si) film, a polysilicon film, a crystal silicon, or a hydrogenated amorphous (a-Si:H), among others. In the embodiment depicted in FIG. 3, the silicon containing film 308 is an a-Si:H film.

Several process parameters and the composition of the second gas mixture are regulated to control the process conditions during the deposition of the silicon containing film 308. In one embodiment, as listed in Table 3, the second gas mixture may include at least a silicon containing gas, such as SiH₄. In another embodiment, the second gas mixture may include at least a silicon containing gas, such as SiH₄, supplied with a hydrogen containing gas, such as H₂ gas.

In an exemplary embodiment, a flow of the second gas mixture includes SiH₄ and H₂ having a total gas flow between about 1,500 sccm to about 4,500 sccm, for example from between about 2,500 sccm to about 3,500 sccm. The gas flow of SiH₄ gas is between about 300 to about 900 sccm, for example, between about 550 to about 750 sccm. The gas flow of H₂ gas is between about 1,500 to about 3,500 sccm, for example, between about 2,000 to about 3,000 sccm. Furthermore, the gas flow ratio between SiH₄ and H₂ (SiH₄:H₂) is between about 1:1 to about 6:1, for example, between about 2:1 to about 5:1.

Additionally, the substrate temperature during the silicon containing film deposition is maintained between about 300 degrees Celsius and about 360 degrees Celsius. The process pressure is maintained at less than about 4 Torr. The RF plasma power is regulated at about less than about 400 Watts.

TABLE 3
Process Parameters regulated while supplying the second gas mixture.

| Process Parameters | Max. | Min. |
|---|---|---|
| SiH₄ (sccm) | 900 | 300 |
| H₂ (sccm) | 3500 | 1500 |
| SiH₄:H₂ gas ratio | 6 | 1 |
| Temperature (degrees | 360 | 300 |
| Celsius) | | |
| Pressure (mTorr) | 4 | 0 |
| RF power at 13.56 MHz (W) | 400 | 0 |

The film properties of the deposited silicon containing semiconductor layer 308 is selected so that a desired performance requirement of a TFT device is obtained. The performance requirement of the film includes having electron mobility higher than 0.8 centimeters squared per voltage per second (cm²/V), a uniformity of film thickness below 15 percent and uniformity of film properties, such as chemical composition and structural characteristics. In one embodiment, the required film properties are achieved by controlling the silicon-hydrogen (Si—H) bonded content of the a-Si:H film, measured by fourier transform infrared spectra (FTIR), less than about 7 atomic weight percent, optical energy gap (E₀₄) less than about 1.84 electron voltage (eV), and the Si—H peak area/unit thickness (Si—H WH/T), measured from FTIR, less than about 0.4, as listed in Table 4.

TABLE 4
Film properties of the a-Si:H gate insulator layer.

| | a-Si:H film |
|---|---|
| Si—H bonding content | <7 percent |
| Optical Gap Energy (E₀₄) | <1.84 eV |
| Si—H WH/T | <0.4 |

With the improved electron mobility of the silicon containing film, a lower threshold voltage shift of the device performance is also achieved. The lower threshold voltage shift enables the TFT devices to operate in a stable and reliable manner, thereby resulting in the improvement of the stability and performance of the device. In one embodiment, an improved threshold voltage shift of greater than 20% is achieved by the selected film properties of the silicon containing film.

At step 410, the substrate is removed from the second process chamber. Subsequently, at step 412, the substrate subjected to further processing, such as depositing a layer 310 of n+ or p+ doped a-Si film is deposited over the silicon containing layer 308 served as a doped semiconductor layer to provide a conductive layer which can later become the source and drain regions of the TFT device. Several process steps including etching steps for patterning the device and/or depositing more layers required to form TFT devices, as exemplified in FIG. 3, may be executed as needed to meet desired device structures.

Thus, the methods described herein advantageously improve the electron mobility, stability and uniformity of TFT devices by controlling the film properties of the gate insulator layer and semiconductor layer.

While the foregoing is directed to embodiments of the present invention, other and further embodiments of the invention may be devised without departing from the basic scope thereof, and the scope thereof is determined by the claims that follow.

1. A method for manufacturing a TFT device having high electron mobility and stability, comprising:
providing a substrate into a first processing chamber;
supplying a first gas mixture into the processing chamber; and
depositing a nitrogen containing layer on the substrate in the first chamber, wherein the nitrogen containing layer film has film properties including a N:Si stiochiometry ratio greater than about 1.5:1, a hydrogen content in the silicon bonding less than about 4.0 atomic weight percent, a wet etching rate at Buffer Oxide Etchant 6:1 solution less than about 400 Å per minute, an optical energy gap greater than about 5.4 electron Voltage, and a dielectric constant greater than about 6.85.

2. The method of claim 1 further comprises:
transferring the substrate into a second process chamber;
supplying a second gas mixture into the second process chamber; and
depositing a silicon containing layer over the nitrogen containing layer on the substrate in the second chamber, wherein the silicon containing layer film has film properties including an optical energy gap less than about 1.84 electron Voltage, a hydrogen content in the silicon bonding less than about 7.0 atomic weight percent, and a Si—H peak area/unit thickness less than about 0.4.

3. The method of claim 1, wherein the step of supplying a first gas mixture further comprises:
supplying the first gas mixture including N₂, NH₃, and SiH₄, wherein the gas flow ratio of NH₃:SiH₄ is about between 8:1 to about 4:1, the gas flow ratio of N₂:SiH₄ is between about 60:1 to about 20:1, and the gas flow ratio of N₂:NH₃ is between about 8.5:1 to about 4.5:1.

4. The method of claim 1, wherein the step of supplying a first gas mixture into the processing chamber further comprises:
maintaining substrate temperature between about 300 to about 360 degrees Celsius;
controlling process pressure between about less than about 2 Torr; and
providing RF power between about 1800 Watts to about 2400 Watts.

5. The method of claim 2, wherein the step of supplying a second gas mixture further comprises:
supplying the second gas mixture SiH₄ and H₂, wherein the gas flow ratio of SiH₄:H₂ is between about 6:1 to about 1:1.

6. The method of claim 2, wherein the step of supplying a second gas mixture into the second processing chamber further comprises:
maintaining substrate temperature between about 300 to about 360 degrees Celsius;
controlling process pressure between less than about 4 Torr; and
providing RF power between less than about 400 Watts.

7. The method of claim 1, wherein the nitrogen containing layer is a SiNₓ:H film.

8. The method of claim 2, wherein the silicon containing layer is an a-Si:H film.

9. The method of claim 2, wherein the second process chamber is the first process chamber.

10. The method of claim 1, wherein the substrate surface area is greater than about 1 meter square (m²).

11. A method for manufacturing a TFT device having high electron mobility and stability, comprising:
providing a substrate into a first processing chamber;
supplying a first gas mixture into the processing chamber;
depositing a nitrogen containing layer on the substrate in the first chamber, wherein the nitrogen containing layer film has film properties including a N:Si stiochiometry ratio greater than about 1.5, a hydrogen content in the silicon bonding less than about 4.0 atomic weight percent, a wet etching rate Buffer Oxide Etchant 6:1 solution less than about 400 Å per minute, an optical energy gap greater than about 5.4 electron Voltage, and a dielectric constant greater than about 6.85;
transferring the substrate into a second process chamber;
supplying a second gas mixture into the second process chamber; and
depositing a silicon containing layer over the nitrogen containing layer on the substrate in the second chamber, wherein the silicon containing layer film has film properties including an optical energy gap less than about 1.84 electron Voltage, a hydrogen content in the silicon bonding less than about 7.0 atomic weight percent, and a Si—H peak area/unit thickness less than about 0.4.

12. The method of claim 11, wherein the step of supplying a first gas mixture into further comprises:
supplying the first gas mixture including N₂, NH₃, and SiH₄, wherein the gas flow ratio of NH₃:SiH₄ is about between 8:1 to about 4:1, the gas flow ratio of N₂:SiH₄ is between about 60:1 to about 20:1, and the gas flow ratio of N₂:NH₃ is between about 8.5:1 to about 4.5:1.

13. The method of claim 11, wherein the step of supplying a first gas mixture into further comprises:
maintaining substrate temperature between about 300 to about 360 degrees Celsius;
controlling process pressure between about less than about 2 Torr; and
providing RF power between about 1800 Watts to about 2400 Watts.

14. The method of claim 11, wherein the step of supplying a second gas mixture further comprises:
supplying the second gas mixture SiH₄ and H₂, wherein the gas flow ratio of SiH₄:H₂ is between about 6:1 to about 1:1.

15. The method of claim 11, wherein the step of supplying a second gas mixture into further comprises:
maintaining substrate temperature between about 300 to about 360 degrees Celsius;
controlling process pressure between about less than about 4 Torr; and
providing RF power between about less than about 400 Watts.

16. The method of claim 11, wherein the nitrogen containing layer is a SiNₓ:H film.

17. The method of claim 11, wherein the silicon containing layer is an a-Si:H film.

18. The method of claim 11, wherein the second process chamber is the first process chamber.

19. The method of claim 11, wherein the substrate surface area is greater than about 1 meter square (m²).

20. A method for manufacturing a TFT device having high electron mobility and stability, comprising:
providing a substrate into a first processing chamber;
supplying a first gas mixture into the processing chamber, wherein the first mixture including N₂, NH₃, and SiH₄, wherein the gas flow ratio of NH₃:SiH₄ is about 8:1 to about 4:1, the gas flow ratio of N₂:SiH₄ is about 60:1 to about 20:1, and the gas flow ratio of N₂:NH₃ is about 8.5:1 to about 4.5:1;
maintaining substrate temperature between about 300 to about 360 degrees Celsius;
controlling process pressure between about less than about 2 Torr;
providing RF power between about 1800 Watts to about 2400 Watts;
depositing a nitrogen containing layer on the substrate in the first chamber;
transferring the substrate into a second process chamber;
providing a second gas mixture into the second process chamber, wherein the second mixture including SiH₄ and H₂, wherein the gas flow ratio of SiH₄:H₂ is about 6:1 to about 1:1;
maintaining substrate temperature between about 300 to about 360 degrees Celsius;
controlling process pressure between about less than about 4 Torr;
providing RF power between about less than about 400 Watts; and
depositing a silicon containing layer over the nitrogen containing layer on the substrate in the second chamber.
